(19) United States
(12) Patent Application Publication
(10) Pub. No.: US 2021/0296046 A1
(43) Pub. Date: Sep. 23, 2021

(54) COIL COMPONENT AND ELECTRONIC DEVICE

(71) Applicant: TAIYO YUDEN CO., LTD., Tokyo (JP)

(72) Inventors: Tomokazu IKENAGA, Takasaki-shi (JP); Kazuyoshi SATO, Takasaki-shi (JP); Makoto TOKONAMI, Takasaki-shi (JP)

(21) Appl. No.: 17/167,942

(22) Filed: Feb. 4, 2021

(30) Foreign Application Priority Data
Mar. 19, 2020 (JP) 2020-049553

(51) Int. Cl. H01F 27/34; H01F 27/24; H01F 27/29; H01F 27/28; H05K 1/18; H01F 41/02; H01F 41/06

(52) U.S. Cl. CPC H01F 27/346; H01F 27/24; H01F 27/292; H01F 27/2885; H05K 1/181; H01F 41/0246; H01F 41/06; H01F 27/2823

(57) ABSTRACT

A coil component includes a coil conductor; a magnetic base body part in which the coil conductor is provided; a conductive resin part provided on the surface of the magnetic base body part and containing multiple magnetic grains and a resin; first external electrodes electrically connected to the coil conductor; and a second external electrode electrically connected to the conductive resin part. The coil component can maintain the Q-characteristics while keeping electric field leakage low.

### CROSS-REFERENCE TO RELATED APPLICATIONS

The present application claims priority to Japanese Patent Application No. 2020-049553, filed Mar. 19, 2020, the disclosure of which is incorporated herein by reference in its entirety including any and all particular combinations of the features disclosed therein.

### BACKGROUND

### Field of the Invention

The present invention relates to a coil component and an electronic device.

### Description of the Related Art

A coil component is used as one of the components constituting a step-down DC-DC converter, for example. In a step-down DC-DC converter, a high-frequency current flows through a coil component as a switching element turns on and off. This means that an electric field or magnetic field may leak from the coil component and cause unwanted effects such as malfunctioning of other devices. Accordingly, coil components having an electric field shielding effect (refer to Patent Literature 1, for example), and coil components having a magnetic field shielding effect (refer to Patent Literature 2, for example), have been proposed.

### BACKGROUND ART LITERATURES

[Patent Literature 1] Japanese Patent Laid-open No. 2019-79942

[Patent Literature 2] Japanese Patent Laid-open No. Hei 11-195542

### SUMMARY

In Patent Literature 1, a metal wire to be connected to ground is wound around the side faces of a magnetic base body part in which a coil conductor is provided, to keep any leakage of electric field low. In a high-frequency use environment, for example, however, the magnetic flux generating in the coil component may change and thereby cause an eddy current to generate in the metal wire, leading to a drop in the Q-value.

The present invention was made in light of the aforementioned problems, and its object is to inhibit the Q-value from dropping while keeping the electric field leakage low.

The present invention is a coil component comprising: a coil conductor; a magnetic base body part in which the coil conductor is provided; a conductive resin part provided on the surface of the magnetic base body part, and containing multiple magnetic grains and a resin; first external electrodes electrically connected to the coil conductor; and a second external electrode electrically connected to the conductive resin part.

The aforementioned constitution may be one wherein the metal grains are non-magnetic metal grains.

The aforementioned constitution may be one wherein the non-magnetic metal grains are grains that contain silver or copper.

The aforementioned constitution may be one wherein the metal grains are magnetic metal grains.

The aforementioned constitution may be one wherein the magnetic metal grains are grains that contain iron or nickel.

The aforementioned constitution may be one wherein the metal grains have a diameter of 10 μm or smaller.

The aforementioned constitution may be one wherein the conductive resin part covers at least a first face of the magnetic base body part.

The aforementioned constitution may be one wherein the conductive resin part extends from the first face, to two faces including a second face and a third face, of the magnetic base body part.

The present invention is an electronic device comprising: the coil component described above; and a circuit board on which the coil component is mounted.

The aforementioned constitution may be one wherein the first external electrodes of the coil component are electrically connected to signal electrodes on the circuit board, while the second external electrode of the coil component is electrically connected to a ground electrode on the circuit board.

According to the present invention, a drop in the Q-value can be inhibited while keeping the electric field leakage low.

### BRIEF DESCRIPTION OF THE DRAWINGS

FIG. 1A is a plan view showing the coil component pertaining to a first embodiment of the invention under the present application for patent, FIG. 1B is a cross-sectional view taken along line A-A′ in FIG. 1A, and FIG. 1C is a cross-sectional view taken along line B-B′ in FIG. 1A.

FIG. 2 is a schematic enlarged cross-sectional view of a part of the conductive resin part according to an embodiment.

FIG. 3 is a schematic enlarged cross-sectional view of a part of the conductive resin part according to another embodiment.

FIG. 4 is a cross-sectional view of the coil component pertaining to a second embodiment of the invention under the present application for patent.

FIG. 5A is a cross-sectional view of the coil component pertaining to a third embodiment of the invention under the present application for patent, and FIG. 5B is a plan view of the same as viewed from the direction of A in FIG. 5A.

FIGS. 6A and 6B are cross-sectional views, taken in directions perpendicular to each other, of the electronic device pertaining to a fourth embodiment of the invention under the present application for patent.

FIG. 7 is a cross-sectional view of the coil component pertaining to Comparative Example 2.

FIG. 8 is a plan view showing an experiment method of evaluating electric field intensity of a coil component.

FIG. 9A is a schematic view showing the measured result of electric field intensity around the coil component pertaining to Comparative Example 1, and FIG. 9B is a schematic view showing the measured result of electric field intensity around the coil component pertaining to Example 1.

FIG. 10 is a graph showing the measured results of Q-values of the coil components pertaining to Examples 1 and 2 and Comparative Examples 1 to 4.

### DESCRIPTION OF THE SYMBOLS

10 Magnetic base body part
12 Winding core part
14 First flange part
16 Second flange part
20 to 28 Face
30 Coil conductor
32 Coated conductive wire
34 Winding part
50, 50a, 50b Conductive resin part
52 Resin
54 Metal grain
60, 62 First external electrode
70 Second external electrode
80 Magnetic resin film
84 Metal plate
90 Circuit board
92, 94 Signal electrode
96 Ground electrode
98 Solder
100, 200, 300 Coil component
400 Electronic device
500 Coil component
510 Evaluation board
512 Copper foil
514 Signal wire

### DETAILED DESCRIPTION OF EMBODIMENTS

Embodiments of the invention under the present application for patent are explained below by referring to the drawings as deemed appropriate. It should be noted, however, that the invention under the present application for patent is not limited to the illustrated modes. Also, components that are common to multiple drawings are indicated using the same reference symbols in all of the multiple drawings. Attention is drawn to the fact that, for the convenience of explanation, each drawing is not necessarily to scale.

### First Embodiment

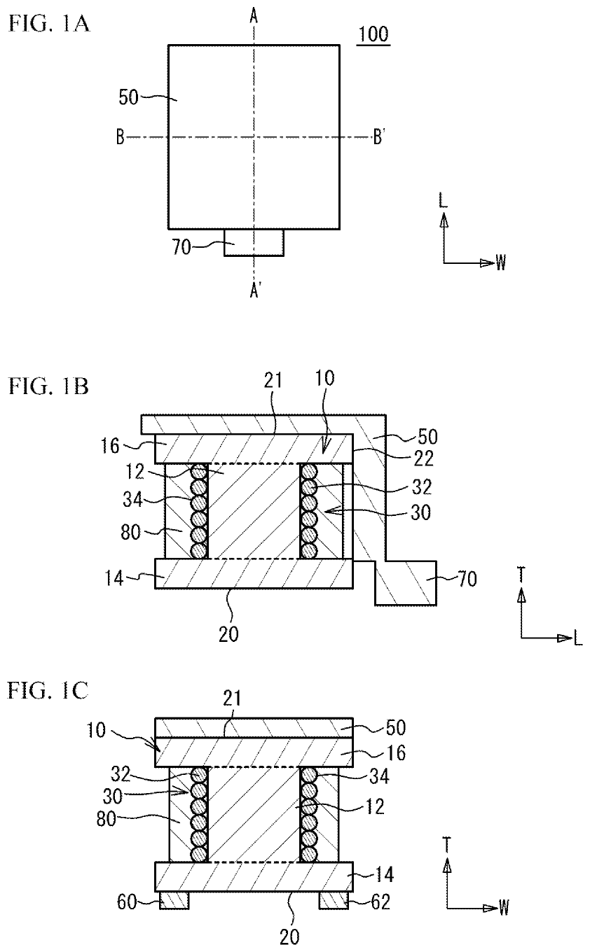

FIG. 1A is a plan view showing the coil component pertaining to the first embodiment of the invention under the present application for patent, FIG. 1B is a cross-sectional view of A-A′ in FIG. 1A, and FIG. 1C is a cross-sectional view of B-B′ in FIG. 1A. Although FIGS. 1A to 1C show an example where the coil component is a power inductor used in a DC-DC converter, for example, they also hold true for different applications.

With reference to FIGS. 1A to 1C, the coil component 100 comprises a magnetic base body part 10, a coil conductor 30, a conductive resin part 50, first external electrodes 60, 62, and a second external electrode 70. The “length” direction, “width” direction and “thickness” direction of the coil component 100 are illustrated as the “L” direction, “W” direction and “T” direction, respectively. The coil component 100 has a length dimension (dimension in the L-axis direction) of 2 to 10 mm, a width dimension (dimension in the W-axis direction) of 2 to 10 mm, and a thickness dimension (dimension in the T-axis direction) of 2 to 5 mm, for example.

The magnetic base body part 10 is, for example, a drum core comprising a winding core part 12, a first flange part 14 provided on one end part of the winding core part 12 in the axial direction, and a second flange part 16 provided on the other end part of the winding core part 12. The first flange part 14 has an exterior-side face 20 of the first flange part 14 on the opposite side to the winding core part 12, while the second flange part 16 has an exterior-side face 21 of the second flange part 16 on the opposite side to the winding core part 12. The faces 20, 21 are exterior-side faces of the magnetic base body part 10, respectively. The winding core part 12 has a circular cross-section shape, for example, but it may have a roughly rectangular, or hexagonal, octagonal, or otherwise polygonal, or elliptical, cross-section shape. The first flange part 14 and second flange part 16 are shaped like a square plate having thickness in the axial direction of the winding core part 12, but they may be shaped like a disk.

The magnetic base body part 10 is a sintered body formed by a Ni-Zn or Mn-Zn ferrite material, for example. The magnetic base body part 10 is not limited to the foregoing, and it may be formed in a manner containing Fe-Si-Cr, Fe-Si-Al, Fe-Si-Cr-Al, or other soft magnetic alloy material, Fe, Ni, or other magnetic metal material, amorphous magnetic metal material, nanocrystal magnetic metal material, or other metal magnetic material. The magnetic base body part 10 may be constituted by any of these metal magnetic materials that have been hardened with a thermosetting or thermoplastic resin, or it may be constituted by metal magnetic materials that have been bonded together via an inorganic material.

The coil conductor 30 includes a winding part 34 comprising a coated conductive wire 32 wound around the winding core part 12, and two lead parts (not illustrated) that have been led out from the winding part 34. The coated conductive wire 32 has a structure in which a core wire made of copper is covered, on its peripheral face, with an insulating film made of polyamide imide, for example. The core wire may be formed by a metal other than copper, and it may be formed by silver, palladium, or silver-palladium alloy, for example. The insulating film may be formed by an insulating material other than polyamide imide, and it may be formed by polyester imide, polyurethane, or other resin material, for example.

The first external electrodes 60, 62 are provided on the first flange part 14. To be specific, the first external electrodes 60, 62 are provided on the exterior-side face 20 of the first flange part 14. The exterior-side face 20 of the first flange part 14 is the surface of the magnetic base body part 10, which means that the first external electrodes 60, 62 are provided on the surface of the magnetic base body part 10. The first external electrodes 60, 62 are connected to the two lead parts, respectively, and electrically connected to the winding part 34 via the lead parts. The first external electrodes 60, 62 are formed by a metal material such as nickel- and tin-plated silver or copper. The first flange part 14, on which the first external electrodes 60, 62 are thus provided, represents a flange part on the bottom face side or mounting face side.

A magnetic resin film 80 is provided in a manner being sandwiched between the first flange part 14 and the second flange part 16 and covering the winding part 34 of the coil conductor 30 at least partially. The magnetic resin film 80 is formed by an insulating resin containing magnetic grains, such as epoxy resin containing ferrite.

The conductive resin part 50 is provided at least on one face, or specifically at least on a first face, among the surfaces of the magnetic base body part 10 (The first face is roughly planar, but it may have slight curvature or depression, e.g., the majority area of the first face is flat). For example, the conductive resin part 50 is provided on the exterior-side face 21 of the second flange part 16. The exterior-side face 21 of the second flange part 16 is the surface of the magnetic base body part 10, which means that the conductive resin part 50 is provided on the exterior side of the surface of the magnetic base body part 10. Furthermore, the conductive resin part 50 extends over a face 22 that connects to the face 21 of the second flange part 16. Thus, the conductive resin part 50 is provided at least on the first face among the surfaces of the magnetic base body part 10. The conductive resin part 50 may cover the first face of the magnetic base body part 10. On the first face of the magnetic base body part 10, the surface area (face size) of the conductive resin part 50 may be the same as that of the first face or may be larger than that of the first face, or the conductive resin part 50 may overlap or cover (in direct or indirect contact with) a majority area or the entire area of the first face.

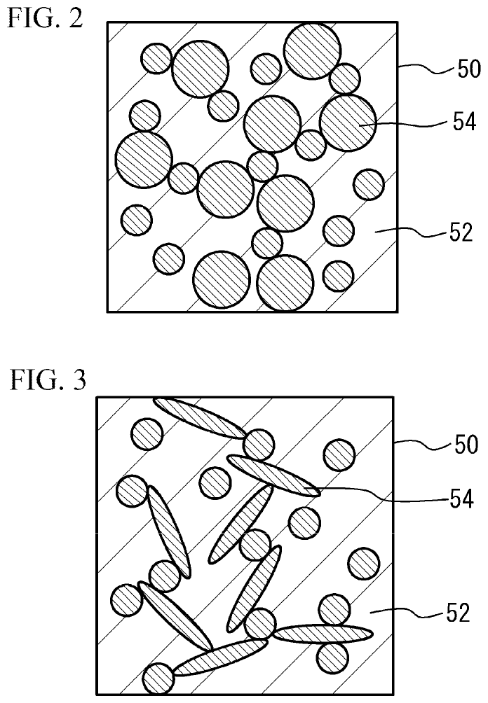

FIG. 2 is an enlarged cross-sectional view of a part of the conductive resin part. With reference to FIG. 2, the conductive resin part 50 has an insulating resin 52 and multiple metal grains 54 dispersed in the resin 52. In the conductive resin part 50, the multiple metal grains 54 are bonded by the resin 52, and the multiple metal grains 54 are partially contacting each other. The resin 52 may be either a thermosetting resin or thermoplastic resin, where epoxy resin, silicone resin, polyimide resin, or polyurethane resin may be used, for example. The metal grains 54 may be non-magnetic metal grains made of aluminum, copper, silver, etc., for example, or magnetic metal grains made of nickel, iron, etc., for example. The multiple metal grains 54 may include different types of metal grains, or they may include metal grains of different diameters. The size of the metal grains 54 is 0.1 to 10 μm in average grain size, for example. The average grain size represents a grain size at cumulative 50 percent based on a granularity distribution obtained according to the laser diffraction/scattering method, for example. In the conductive resin part 50, the volume percentage of the metal grains 54 is 40 to 50 percent by volume, and the remainder may be the resin 52 and ceramic grains or other inorganic filler contained for the purpose of resistance adjustment and/or viscosity adjustment, for example. Furthermore, the conductive resin part 50 has higher resistance in parts where the multiple metal grains 54 are bonded together via the resin 52, and achieves electrical continuity in parts where the multiple metal grains 54 are contacting each other. The specific resistance of this conductive resin part 50 is 1×10⁻⁶ to 1×10⁻⁴ Ω·m, for example.

With reference to FIGS. 1A to 1C, the second external electrode 70 is electrically connected to the conductive resin part 50. The second external electrode 70 is formed by the same material as for the conductive resin part 50, having the resin 52 and the multiple metal grains 54 dispersed in the resin 52, for example. The bottom face of the second external electrode 70 is flush with the bottom faces of the first external electrodes 60, 62, for example. The second external electrode 70 is electrically insulated from the first external electrodes 60, 62. There may be one, two, or more second external electrode or electrodes 70, and whichever the case may be, the second external electrode(s) 70 is/are electrically connected to the conductive resin part 50 and insulated from the first external electrodes 60, 62. When the coil component 100 is mounted on a circuit board, the first external electrodes 60, 62 are electrically connected to signal electrodes on the circuit board, while the second external electrode 70 is electrically connected to a ground electrode on the circuit board.

[Manufacturing Method]

An example of how the coil component pertaining to the first embodiment is manufactured, is explained. First, the magnetic base body part 10 is formed. The magnetic base body part 10 is formed, for example, by filling into the cavity of a die a granulated powder prepared by mixing a ferrite powder and a resin, press-forming the granulated powder to form a drum-shaped compact, and then heat-treating the compact. The coil conductor 30 is formed from a winding part 34 prepared by winding a coated conductive wire 32 around the winding core part 12 of the magnetic base body part 10, and also from lead parts that have been led out from the winding part 34 and stripped of the coating film. The magnetic resin film 80 is formed by applying in a manner covering the winding part 34 a paste prepared by mixing magnetic grains into a resin, and then curing the resin component. The conductive resin part 50 is formed by applying onto the surface of the magnetic base body part 10 a paste prepared by mixing metal grains into a resin, and then curing the resin component. The first external electrodes 60, 62 are formed as metal films by means of printing, plating, sputtering, or other method used in thin-film treatment, and the lead parts of the coil conductor 30 are connected thereto. The second external electrode 70 is formed in the same manner as the conductive resin part 50, and connected to the conductive resin part 50.

According to the first embodiment, the conductive resin part 50 containing the multiple metal grains 54 and resin 52 is provided on the surface of the magnetic base body part 10 in which the coil conductor 30 is provided. The coil conductor 30 is electrically connected to the first external electrodes 60, 62, and the conductive resin part 50 is electrically connected to the second external electrode 70. Because the conductive resin part 50 containing the metal grains 54 is provided on the surface of the magnetic base body part 10, the electric field generating from the coil conductor 30 is attenuated as it passes through the conductive resin part 50 in a condition where the second external electrode 70 is connected to ground, and this allows the electric field intensity generating around the coil component 100 to be kept low. Additionally, as the magnetic flux generating in the coil component 100 passes through the conductive resin part 50, generation of eddy current is held back in each metal grain 54 because the conductive resin part 50, which is constituted by a mixture of the metal grains 54 and resin 52 where the metal grains 54 are in a dispersed state, is designed to carry conductivity and produce a prescribed resistance, and consequently the size of eddy current generated by the conductive resin part 50 as a whole can be kept low. This way, a drop in the Q-value can be inhibited. According to the first embodiment, the coil component thus obtained can inhibit loss from worsening, while keeping electric field leakage low.

The metal grains 54 contained in the conductive resin part 50 may be non-magnetic metal grains or magnetic metal grains. Also, the metal grains 54 may include both non-magnetic metal grains and magnetic metal grains.

The metal grains 54, if non-magnetic metal grains, may be grains that contain silver or copper. If the metal grains 54 are non-magnetic metal grains, eddy currents generating in the metal grains 54 become small and consequently a drop in the Q-value can be inhibited further. The metal grains 54 may be silver grains or copper grains, or they may be silver or copper alloy grains. Preferably the metal grains 54 are made of a metal material of low resistivity and have a small grain size. This way, eddy currents generating in the metal grains 54 can be reduced. For example, resistivity of the metal material for the metal grains 54 is preferably 3.0×10⁻⁸ Ω·m or lower, or more preferably 2.0×10⁻⁸ Ω·m or lower. The metal grains 54 have a grain size (dimension of the longest part) of preferably 10 μm or smaller, or more preferably 8 μm or smaller, or yet more preferably 6 μm or smaller. Also, the metal grains 54 are not limited to a spherical shape and may have other shapes. FIG. 3 is an enlarged cross-sectional view of a part of other example of the conductive resin part. With reference to FIG. 3, the conductive resin part 50 may contain metal grains 54 having a shape that has length, such as a scale-like, needle-like, or other elliptical shape, or rectangular shape. If the metal grains 54 are scale-like or needle-like, for example, the respective metal grains 54 only need to be small in volume. This way, the conductive resin part 50 can achieve a desired resistance and also inhibit a drop in the Q-value further, due to the sizes of the metal grains 54 and dispersion of the metal grains 54 in the resin 52. Additionally, when they are non-magnetic metal grains, the metal grains 54 do not generate magnetic flux and thus will not cause eddy current to generate.

The metal grains 54, if magnetic metal grains, may be grains that contain iron or nickel. If the metal grains 54 are magnetic metal grains, not only the effect of inhibiting electric field leakage, but also the magnetic shielding effect to inhibit magnetic flux leakage from the coil component 100, can be obtained. In this case, preferably the conductive resin part 50 is placed in the direction of magnetic flux leakage. For example, preferably the conductive resin part 50 is provided in a thin part of the magnetic base body part 10, and if the magnetic base body part 10 is a drum core, preferably it is provided on the side faces of the first flange part 14 and second flange part 16. The metal grains 54 may be iron grains or nickel grains, or they may be iron or nickel alloy grains. Preferably the metal grains 54 are small in grain size. This way, eddy currents generating in the metal grains 54 can be reduced. Additionally, if the metal grains 54 are iron grains, preferably their grain sizes are 1 μm or larger to prevent spontaneous combustion. If the metal grains 54 are nickel grains, their grain sizes may be adjusted to 1 μm or smaller.

The conductive resin part 50 is provided on a first face of the magnetic base body part 10 (such as the exterior-side face 21 of the second flange part 16) and may cover the first face. This way, magnetic field leakage in the direction intersecting the first face of the magnetic base body part 10 covered with the conductive resin part 50, can be kept low. Also, the conductive resin part 50 may be provided thinly, like a film, on the first face of the magnetic base body part 10. This way, eddy current generating in the conductive resin part 50 can be kept low. Thus, preferably the conductive resin part 50 is a thin film covering a large area. In the case of the coil component in the first embodiment, for example, the face 21 represents the top face of the coil component. Also, an adhesive layer or insulating layer may be provided on the first face of the magnetic base body part 10, and the conductive resin layer 50 may be provided on the exterior side of the magnetic base body part 10 via a part of the adhesive layer or insulating layer. Presence of the adhesive layer or insulating layer can further enhance the insulation between the conductive resin layer 50 and the magnetic base body part 10.

The conductive resin part 50 is such that, to keep generating eddy current low, preferably 80 percent or higher of the metal grains 54 are bonded via the resin 52, or more preferably 90 percent or higher of them are bonded via the resin 52, or yet more preferably 95 percent or higher of them are bonded via the resin 52.

In the conductive resin part 50, the volume percentage of the metal grains 54 is preferably 30 percent by volume or higher, or more preferably 35 percent by volume or higher, or yet more preferably 40 percent by volume or higher, to keep electric field leakage low. To keep generating eddy current low, on the other hand, the volume percentage of the metal grains 54 is preferably 60 percent by volume or lower, or more preferably 55 percent by volume or lower, or yet more preferably 50 percent by volume or lower.

### Second Embodiment

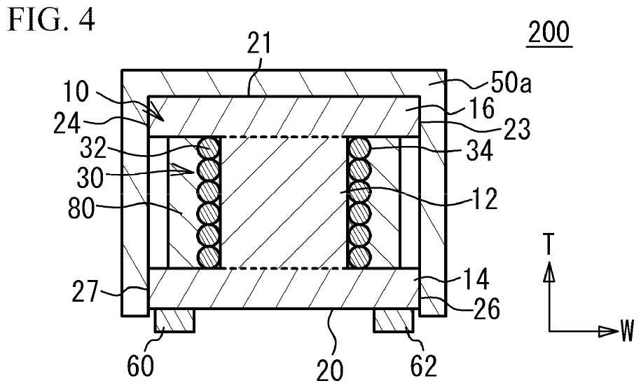

FIG. 4 is a cross-sectional view of the coil component pertaining to the second embodiment of the invention under the present application for patent. With reference to FIG. 4, the coil component 200 is such that a conductive resin part 50a extends from a first face, to second and third faces, of the magnetic base body part 10. For example, the conductive resin part 50a is provided on the exterior side of the face 21 of the second flange part 16, as well as on the exterior sides of exterior-side faces 23, 24 of the second flange part that connect to the face 21. Also, the conductive resin part 50a extends further to exterior-side faces 26, 27 of the first flange part 14. The conductive resin part 50a may cover each of the faces 21, 23, 24, 26, and 27 in its entirety. The remaining constitutions are the same as those in the first embodiment and therefore not explained.

According to the second embodiment, the conductive resin part 50a extends from a first face (such as the exterior-side face 21 of the second flange part 16), to two faces including a second face (such as the exterior-side face 23 of the second flange part 16) and a third face (such as the exterior-side face 24 of the second flange part 16), of the magnetic base body part 10. The faces 23, 24 form faces that are different from the face 21. This way, electric field leakage can be kept low on each of the three faces. In the case of the coil component in the second embodiment, for example, the face 21 represents the top face of the coil component, while the faces 23, 24, 26, 27 represent the side faces of the coil component.

### Third Embodiment

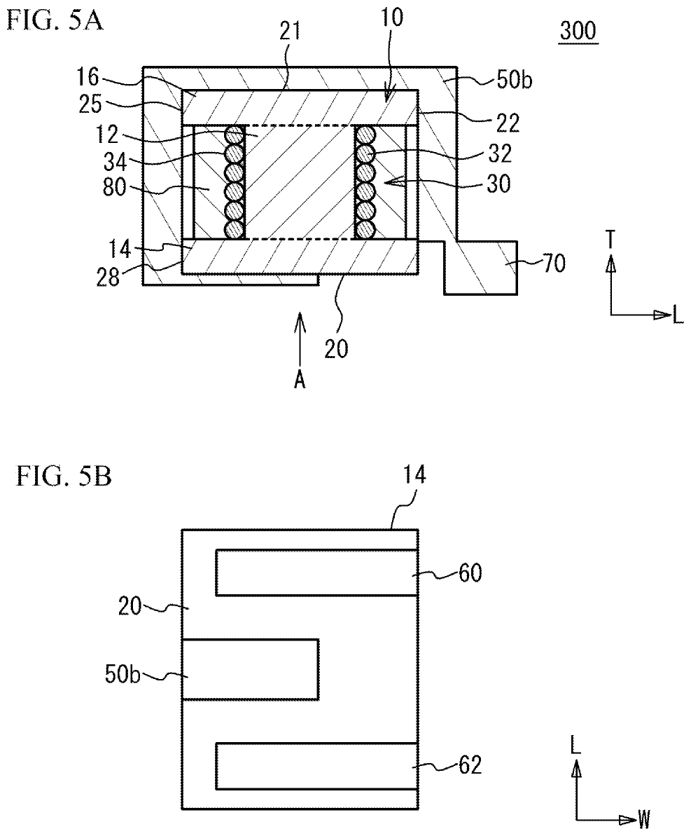

FIG. 5A is a cross-sectional view of the coil component pertaining to the third embodiment of the invention under the present application for patent, and FIG. 5B is a plan view of the same as seen from the direction of A in FIG. 5A. With reference to FIGS. 5A and 5B, the coil component 300 is such that a conductive resin part 50b extends from a first face of the magnetic base body part 10 to the faces on which the first external electrodes 60, 62 are provided. For example, the conductive resin part 50b is provided on the exterior side of the face 21 of the second flange part 16, as well as on the exterior side of the exterior-side face 25 of the second flange part 16 that connects to the face 21, and extends to the face 20 of the first flange part 14 via the exterior-side face 28 of the first flange part 14. The conductive resin part 50b may cover the faces 21, 25, 28 in their entirety, as well as a part of the face 20. The remaining constitutions are the same as those in the first embodiment and therefore not explained. In the third embodiment, electric field leakage in the direction intersecting the multiple faces of the magnetic base body part 10 can also be kept low.

While the first through third embodiments showed examples of coil components whose coil conductor 30 is wound around the surface of the magnetic base body part 10, the present invention also covers a coil component whose coil conductor 30 is built into the magnetic base body part 10, or a coil component of any type such as winding, multi-layer or thin-film.

### Fourth Embodiment

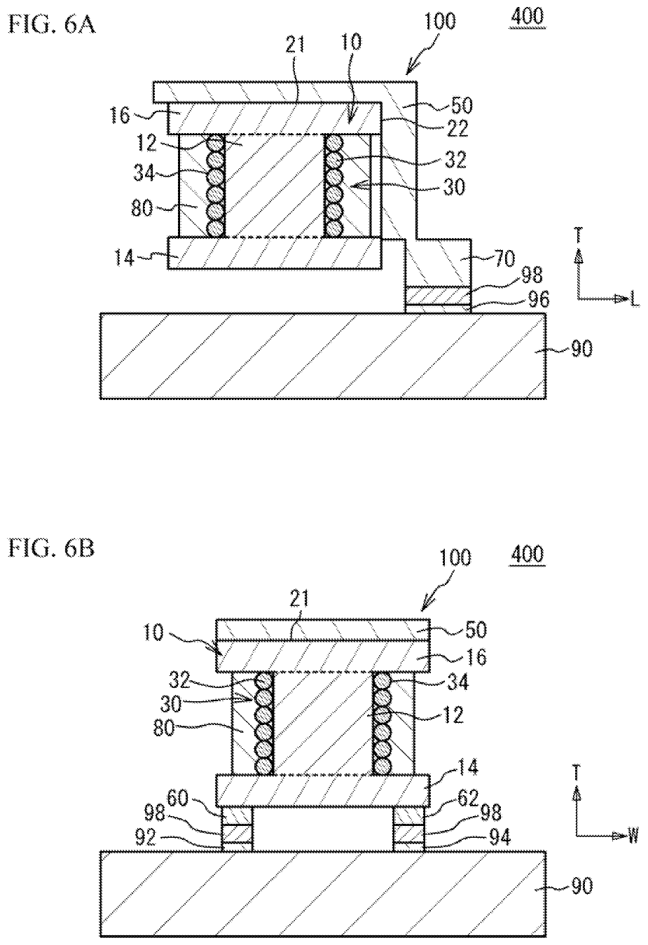

FIGS. 6A and 6B are cross-sectional views of the electronic device pertaining to the fourth embodiment of the invention under the present application for patent. With reference to FIGS. 6A and 6B, the electronic device 400 comprises a circuit board 90 and the coil component 100 mounted on the circuit board 90. The coil component 100 is mounted on the circuit board 90 by way of the first external electrodes 60, 62 being electrically connected via a solder 98 to signal electrodes 92, 94 on the circuit board 90, and the second external electrode 70 being electrically connected via a solder 98 to a ground electrode 96 on the circuit board 90. This way, an electronic device 400 comprising the coil component 100 in which electric field leakage is kept low and a drop in the Q-value is also inhibited, can be obtained.

While the fourth embodiment illustrated an example where the coil component 100 pertaining to the first embodiment is mounted on the circuit board 90, the coil component 200 pertaining to the second embodiment or coil component 300 pertaining to the third embodiment may be mounted on the circuit board 90 instead.

### EXAMPLES

The invention under the present application for patent is explained more specifically below using examples and comparative examples; it should be noted, however, that the invention under the present application for patent is not limited to the modes described in these examples.

### Example 1

The coil component in the first embodiment shown in FIGS. 1A to 1C was produced as the coil component in Example 1. The external dimensions of the coil component were 6.0 mm in length dimension, 6.0 mm in width dimension, and 4.5 mm in thickness dimension. As the magnetic base body part 10, a drum core was formed by mixing a ferrite powder with a resin, followed by press-forming, and then by sintering through heat treatment. The coil conductor 30 was formed using a coated conductive wire comprising a core wire made of copper which is covered, on its peripheral face, with an insulating film made of polyamide imide. The conductive resin part 50 was formed by applying to a thickness of 0.5 mm a paste prepared by mixing silver grains of 1 μm in diameter in an epoxy resin. In the conductive resin part 50, the volume percentage of the metal grains 54 was set to 50 percent by volume. The specific resistance of the paste was adjusted to 2.0×10⁻⁶ Ω·m. The magnetic resin film 80 was formed with an epoxy resin containing ferrite. The inductance value was set to 22 μH.

### Example 2

The conductive resin part 50 was formed using a paste prepared by mixing nickel grains of 1 μm in diameter in an epoxy resin. In the conductive resin part 50, the volume percentage of the metal grains 54 was set to 45 percent by volume. The remaining constitutions were the same as those in Example 1.

### Comparative Example 1

The same constitutions in Example 1 were followed, except that the conductive resin part 50 and second external electrode 70 were not provided.

### Comparative Example 2

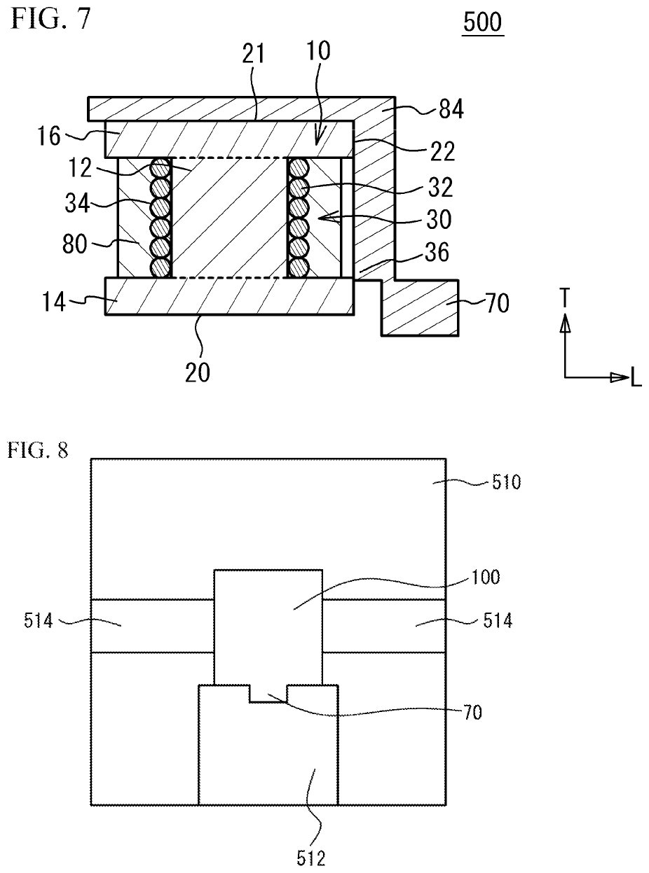

FIG. 7 is a cross-sectional view of the coil component 500 pertaining to Comparative Example 2. With reference to FIG. 7, the coil component 500 in Comparative Example 2 used a metal plate 84, or specifically a silver plate of 0.5 mm in thickness, instead of the conductive resin part 50. The inductance value was set to 22 just like in Example 1. The remaining constitutions were the same as those in Example 1.

### Comparative Example 3

The same constitutions in Comparative Example 2 were followed, except that an aluminum plate of 0.5 mm in thickness was used for the metal plate 84.

### Comparative Example 4

The same constitutions in Comparative Example 2 were followed, except that a nickel plate of 0.5 mm in thickness was used for the metal plate 84.

The differences among Examples 1 and 2 and Comparative Examples 1 to 4 are summarized in Table 1.

TABLE 1

| | Conductive resin part | Metal plate |
|---|---|---|
| Example 1 | Epoxy resin + Silver grains | — |
| Example 2 | Epoxy resin + Nickel grains | — |
| Comparative Example 1 | — | — |
| Comparative Example 2 | — | Silver plate |
| Comparative Example 3 | — | Aluminum |
| | | plate |
| Comparative Example 4 | — | Nickel plate |

[Evaluation of Electric Field Intensity]

An experiment designed for evaluation of electric field intensity was conducted on Example 1 and Comparative Example 1. FIG. 8 is a plan view showing the constitution used in the experiment. With reference to FIG. 8, the coil components 100 in Example 1 and Comparative Example 1 were each mounted on the top face of an evaluation board 510 and the electric field intensity around the coil component 100 was measured. For the evaluation board 510, a FR4 board of 20 mm in length, 20 mm in width, and 1.6 mm in thickness was used. A copper foil 512 of 3 mm in width and 35 μm in thickness was provided on the evaluation board 510 from its top face to bottom face and, in Example 1, the conductive resin part 50 was electrically connected to the copper foil 512 via the second external electrode 70, and thus to the ground of the measuring equipment. Meanwhile, in Comparative Example 1 where there was no second external electrode, the evaluation board 510 was not connected to the copper foil 512. The coil components 100 in Example 1 and Comparative Example 1 each had its first external electrodes 60, 62 electrically connected to signal wires 514, and by applying to the coil conductor 30 a triangle wave current of 1.5 Ap-p with a switching frequency of 200 kHz, the electric field intensity 0.5 mm above the top face of the coil component was measured at a measurement frequency of 1 MHz.

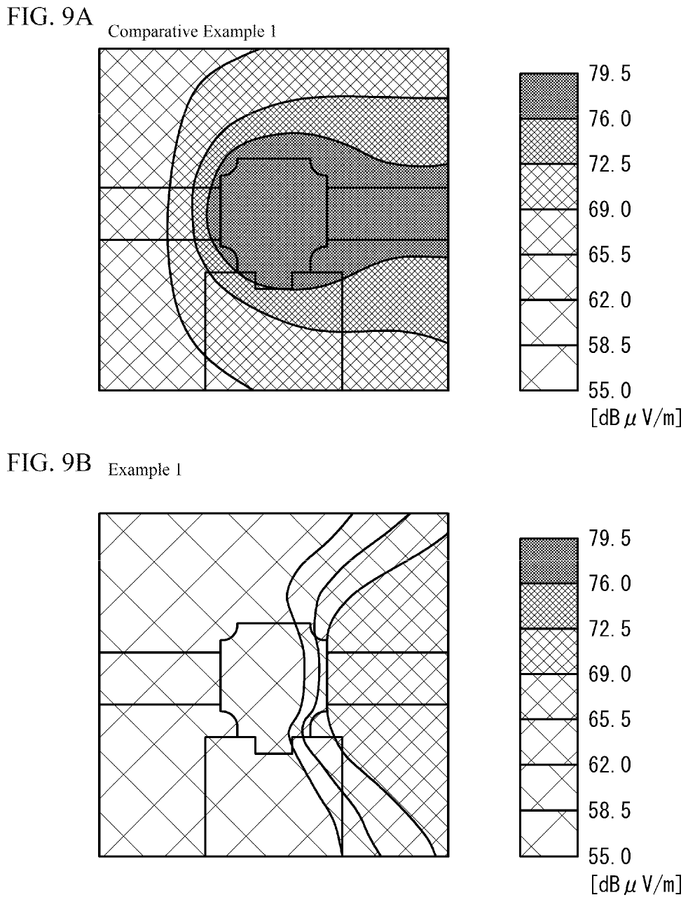

FIG. 9A shows the result of measured electric field intensity around the coil component pertaining to Comparative Example 1, and FIG. 9B shows the result of measured electric field intensity around the coil component pertaining to Example 1. Comparison of FIGS. 9A and 9B finds that, in Example 1 where the conductive resin part 50 was provided on the surface of the magnetic base body part 10, electric field intensity was kept lower than in Comparative Example 1 where the conductive resin part 50 was not provided. The reason the electric field leakage was kept lower in Example 1 than in Comparative Example 1 is assumed as follows. In Example 1, electric field generating from the coil conductor 30 passes through the conductive resin part 50 provided on the surface of the magnetic base body part 10. Since the conductive resin part 50 has the metal grains 54 in the resin 52, electric field attenuates as it passes through the conductive resin part 50. Also, while the current attributable to electric field flows from the conductive resin part 50 to the second external electrode 70, the second external electrode 70 is connected to ground. As a result, it is considered that, in Example 1, electric field generating from the coil conductor 30 was shielded by the conductive resin part 50 and consequently electric field intensity around the coil component was kept low. The results in FIGS. 9A and 9B confirm that, by providing the conductive resin part 50 containing the metal grains 54 and resin 52 on the surface of the magnetic base body part 10 and then electrically connecting the conductive resin part 50 to the second external electrode 70, electric field leakage can be kept low.

[Evaluation of Q-characteristics]

Examples 1 and 2 and Comparative Examples 1 to 4 were evaluated for Q-characteristics. The evaluation of Q-characteristics was performed by installing each coil component on a test fixture and then measuring its Q-value with the RF impedance/material analyzer E4991A manufactured by Keysight Technologies, Inc. The conductive resin part 50 in Examples 1 and 2, or the metal plate 84 in Comparative Examples 2 to 4, was electrically connected to the ground of the test fixture via the second external electrode 70, and thus to the ground of the measuring equipment.

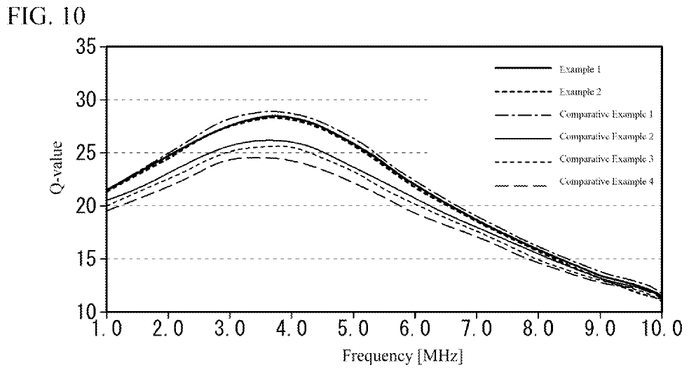

FIG. 10 shows the measured results of Q-values of the coil components pertaining to Examples 1 and 2 and Comparative Examples 1 to 4. With reference to FIG. 10, Examples 1 and 2 where the conductive resin part 50 was used, achieved Q-values roughly equal to that in Comparative Example 1 where neither the conductive resin part 50 nor metal plate 84 was used. In contrast, Comparative Examples 2, 3, and 4 where the metal plate 84 was used, resulted in significantly lower Q-values than in Comparative Example 1. For example, a comparison of Q-values at a frequency of 4 MHz finds that, when Comparative Example 1 is used as the reference, the results of Comparative Examples 2, 3, and 4 were lower by more than 10 percent, or specifically −10.0, −11.7, and −15.9 percent, respectively, while the results of Examples 1 and 2 were lower by no more than 5 percent, or specifically −1.6 and −2.3 percent, respectively.

The reason the Q-values were higher in Examples 1 and 2 than in Comparative Examples 2 to 4 is assumed as follows. Magnetic flux that generates in the coil component passes through the metal plate 84 in Comparative Examples 2 to 4. As magnetic flux passing through the metal plate 84 changes, eddy current generates in the metal plate 84. The metal plate 84 is formed by a metal material alone, which facilitates the flow of current throughout the metal plate 84 and allows large eddy current to generate. If the metal plate 84 is formed by a magnetic material, eddy current generating in the metal plate 84 may cause magnetic flux to generate, resulting in generation of more eddy current. In Examples 1 and 2, on the other hand, magnetic flux that generates in the coil component passes through the conductive resin part 50. The conductive resin part 50, which is constituted by a mixture of the metal grains 54 and resin 52 where the metal grains 54 are provided in the resin in a dispersed state, is designed to carry conductivity and produce a prescribed resistance. Accordingly, generation of eddy current is held back in each metal grain 54 and consequently the size of eddy current generated by the conductive resin part 50 as a whole can be kept low. This is likely why a drop in the Q-value was reduced in Examples 1 and 2. The results in FIG. 10 confirm that, by providing the conductive resin part 50 containing the metal grains 54 and resin 52 on the surface of the magnetic base body part 10, a drop in the Q-value is reduced and therefore worsening of loss can be inhibited.

The results in FIG. 10 confirm that, while the metal grains 54 contained in the conductive resin part 50 could keep a drop in the Q-value to around the same level regardless of whether they were non-magnetic grains as is the case in Example 1 or magnetic grains as is the case in Example 2, the Q-value in Example 1 where non-magnetic grains were used was slightly higher than that in Example 2 where magnetic grains were used. Although Examples 1 and 2 resulted in a small Q-value difference, Comparative Examples 2 to 4 produced large Q-value differences between when the metal plate 84 contained non-magnetic grains (Comparative Examples 2 and 3) and when it contained magnetic grains (Comparative Example 4), which goes to show that the Q-value increases when non-magnetic grains are used for the metal grains 54 compared to when magnetic grains are used. This is likely because a further generation of eddy current due to magnetic flux generating as a result of the eddy current described above, is inhibited.

The foregoing described embodiments of the invention under the present application for patent in detail; it should be noted, however, that the invention under the present application for patent is not limited to such specific embodiments and that various modifications/changes can be made to the extent that doing so does not deviate from the key points of the invention under the present application for patent as explicitly, implicitly, or inherently described herein.

We/I claim:

1. A coil component comprising:
a coil conductor;
a magnetic base body part in which the coil conductor is provided;
a conductive resin part provided on a surface of the magnetic base body part and containing multiple magnetic grains and a resin;
first external electrodes electrically connected to the coil conductor; and
a second external electrode electrically connected to the conductive resin part and electrically insulated from the coil conductor and the first external electrodes.

2. The coil component according to claim 1, wherein the metal grains are non-magnetic metal grains.

3. The coil component according to claim 2, wherein the non-magnetic metal grains are grains that contain silver or copper.

4. The coil component according to claim 1, wherein the metal grains are magnetic metal grains.

5. The coil component according to claim 4, wherein the magnetic metal grains are grains that contain iron or nickel.

6. The coil component according to claim 1, wherein the metal grains have a diameter of 10 μm or smaller.

7. The coil component according to claim 1, wherein the conductive resin part covers at least a first face of the magnetic base body part.

8. The coil component according to claim 7, wherein the conductive resin part extends from the first face, to two faces including a second face and a third face, of the magnetic base body part.

9. An electronic device comprising:
the coil component according to claim 1; and
a circuit board on which the coil component is mounted.

10. The electronic device according to claim 9, wherein the first external electrodes of the coil component are electrically connected to signal electrodes on the circuit board, while the second external electrode of the coil component is electrically connected to a ground electrode on the circuit board.
